(19) United States
(12) Patent Application Publication
(10) Pub. No.: US 2014/0099232 A1
(43) Pub. Date: Apr. 10, 2014

(54) SHEET OF SEMICONDUCTING MATERIAL, SYSTEM FOR FORMING SAME, AND METHOD OF FORMING SAME

(71) Applicant: Corning Incorporated, Corning, NY (US)

(72) Inventors: Samir Biswas, Horseheads, NY (US); Douglass Lane Blanding, Painted Post, NY (US); Glen Bennett Cook, Elmira, NY (US); Prantik Mazumder, Ithaca, NY (US); Kamal Kishore Soni, Painted Post, NY (US); Balram Suman, Katy, TX (US)

(73) Assignee: Corning Incorporated, Corning, NY (US)

(21) Appl. No.: 13/841,995

(22) Filed: Mar. 15, 2013

Related U.S. Application Data
(60) Provisional application No. 61/711,506, filed on Oct. 9, 2012.

(51) Int. Cl. H01L 33/02; H01L 21/02

(52) U.S. Cl. CPC H01L 33/02; H01L 21/02
USPC 420/556; 164/480; 164/428; 420/579; 420/578

(57) ABSTRACT

A method of forming a sheet of semiconductor material utilizes a system. The system comprises a first convex member extending along a first axis and capable of rotating about the first axis and a second convex member spaced from the first convex member and extending along a second axis and capable of rotating about the second axis. The first and second convex members define a nip gap therebetween. The method comprises applying a melt of the semiconductor material on an external surface of at least one of the first and second convex members to form a deposit on the external surface of at least one of the first and second convex members. The method further comprises rotating the first and second convex members in a direction opposite one another to allow for the deposit to pass through the nip gap, thereby forming the sheet of semiconductor material.

### CROSS-REFERENCE TO RELATED APPLICATIONS

This application claims the benefit of priority under 35 U.S.C. §119 of U.S. Provisional Application Ser. No. 61/711,506 filed on Oct. 9, 2012, the content of which is relied upon and incorporated herein by reference in its entirety.

### BACKGROUND

The disclosure relates to a system for forming a sheet of semiconductor material, a method of forming the sheet of semiconductor material with the system, and a sheet of semiconductor material formed with the method.

Semiconductor materials are used in a variety of applications, and may be incorporated, for example, into electronic devices such as photovoltaic devices. The properties of semiconductor materials may depend on a variety of factors, including crystal structure, the concentration and type of intrinsic defects, and the presence and distribution of dopants and other impurities. Within a semiconductor material, the grain size and grain size distribution, for example, can impact the performance of resulting devices. One type of semiconductor material is silicon, which may be formed via a variety of techniques, e.g. as an ingot, sheet or ribbon. The silicon may be supported or unsupported by an underlying substrate.

Small sheets of semiconductor materials can be prepared by a variety of batch methods. One batch method of forming such small sheets is referred to as an exocasting process in which a mold having a small shape that can be placed into a crucible is dipped into a melt of a semiconductor material disposed in the crucible. The mold is then removed from the melt of the semiconductor material and a small sheet forms on surfaces of the mold, which can subsequently be removed and refined or otherwise utilized. However, the sheet of the semiconductor material formed in such conventional methods is limited in dimension based on the size of the mold utilized, and thus these conventional methods can be particularly time consuming to obtain a significant volume of the small sheets of the semiconductor materials. Further, such conventional methods are batch processes, which further limit a rate at which sheets of semiconductor materials can be prepared.

### SUM MARY

The disclosure provides a method of forming a sheet of semiconductor material with a system. The system comprises a first convex member extending along a first axis and capable of rotating about the first axis. The system further comprises a second convex member spaced from the first convex member and extending along a second axis and capable of rotating about the second axis. The first and second axes are substantially parallel with one another and the first and second convex members define a nip gap therebetween. The method comprises applying a melt of the semiconductor material on an external surface of at least one of the first convex member and the second convex member to form a deposit on the external surface of at least one of the first and second convex members. The method further comprises rotating the first and second convex members about the first and second axes, respectively, in a direction opposite one another to allow for the deposit to pass through the nip gap, thereby forming the sheet of semiconductor material.

The disclosure also provides a system for forming the sheet of semiconductor material with the method. Finally, the disclosure provides a sheet of semiconductor material formed with the method.

### BRIEF DESCRIPTION OF THE DRAWINGS

Other advantages and aspects may be described in the following detailed description when considered in connection with the accompanying drawings wherein:

FIG. 1 is a schematic cross-sectional view of one embodiment of a system for forming a sheet of semiconductor material;

FIG. 2 is a is a schematic cross-sectional view of another embodiment of the system for forming the sheet of semiconductor material;

FIG. 3 is a schematic perspective view of the embodiment of FIG. 2; and

FIG. 4 is a perspective view of another embodiment of the system for forming a sheet of semiconductor material.

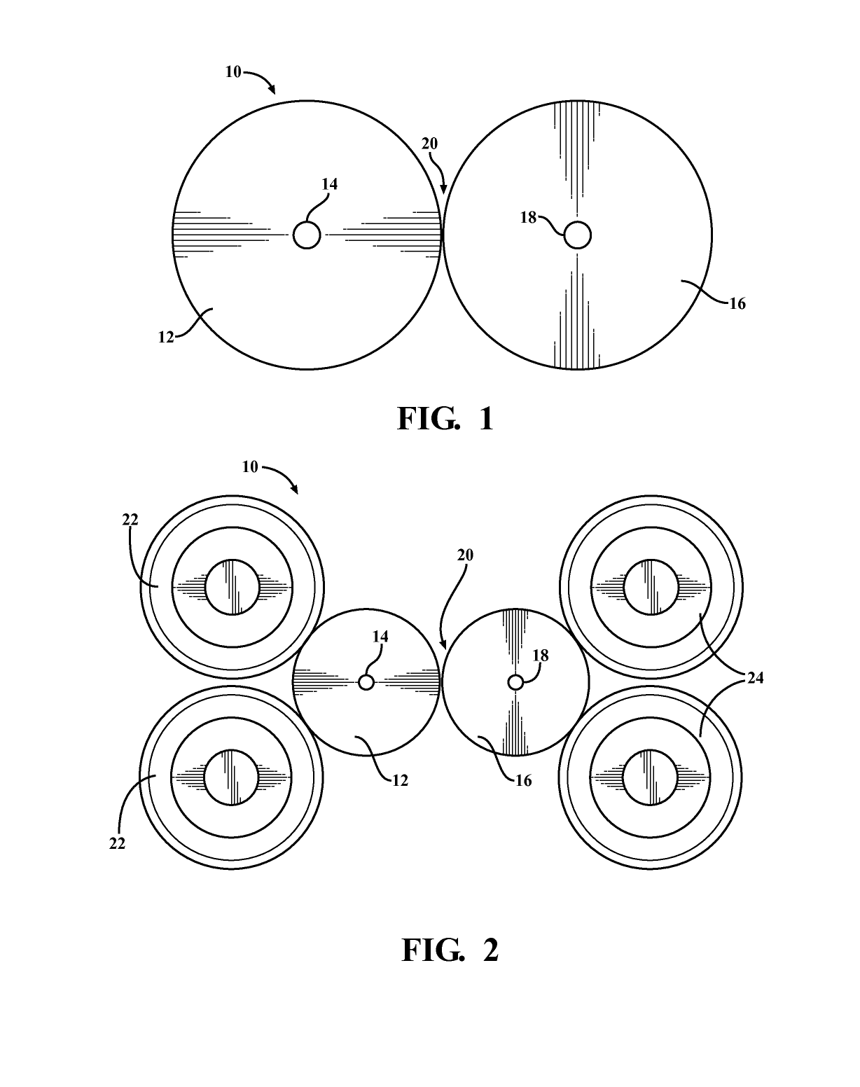

### DETAILED DESCRIPTION OF THE DISCLOSURE

The disclosure provides a method of forming a sheet of semiconductor material with a system. The disclosure also provides a system 10 for forming the sheet of semiconductor material in accordance with the method. Finally, the disclosure provides a sheet of semiconductor material formed with the system 10 and method. The sheet of semiconductor material formed via the method and system 10 is particularly suitable for electronics applications and components, such as microprocessors and photovoltaic cell modules.

The system 10 is utilized to form the sheet of semiconductor material from a melt of a semiconductor material. The system 10 utilized for forming the sheet of semiconductor material comprises a first convex member 10 extending along a first axis 14 and capable of rotating about the first axis 14. The system 10 further comprises a second convex member 16 spaced from the first convex member 12 and extending along a second axis 18 and capable of rotating about the second axis 18. The first and second convex members 12, 16 define a nip gap 20 therebetween. In various embodiments, due in large part to heat loss to at least one of the first and second convex members and the surroundings, at least a portion of the melt of the semiconductor material undergoes a liquid-to-solid phase transformation, which results in the formation of a deposit of semiconductor material on an external surface of at least one of the first and second convex members 12, 16. In the system 10, at least one of the first and second convex members 12, 16 act as a heat sink and a solid form or mold for the solidification to occur. The sheet of semiconductor material is formed as the deposit passes through the nip gap 20, as described below with reference to the method.

The first and second convex members 12, 16 of the system 10 have a generally convex shape. The external surface of each of the first and second members 12, 16 has the generally convex shape. The first and second convex members 12, 16 need not have the entireties of their respective external surfaces present the generally convex shape. For example, the first and second convex members 12, 16 may independently be cylindrical, partially cylindrical, elliptical, partially elliptical, partially spherical, or may be any shape having an arced portion to provide the convex shape. The first and/or second convex members 12, 16 have a perimeter and may be generally rectangular wherein from greater than 0 to less than 360 degrees of the perimeter, i.e., the external surface, has the arced portion to present the convex shape. The first and second convex members 12, 16 may be identical to one another or may be different from one another in terms of size, shape, and/or material.

The first and second axes 14, 18 of the first and second convex members 12, 16, respectively, are substantially parallel with one another. In particular, by “substantially parallel,” it is meant that the first and second axes 14, 18 are generally in the same horizontal plane and form an acute angle of less than 5, alternatively less than 4, alternatively less than 3, alternatively less than 2, alternatively less than 1, degree at an intersection, if any, of the first and second axes 14, 18. The horizontal plane may be angled dependent upon a perspective of the horizontal plane.

The first and second convex members 12, 16 typically each have a substantially uniform and continuous cross section along the first and second axes 14, 18, respectively. The phrase “substantially uniform and continuous,” as used herein with reference to the cross sections of the first and second convex members 12, 16, means a cross-sectional variation of less than 30, alternatively less than 20, alternatively less than 10, alternatively less than 5, alternatively less than 2, alternatively less than 1, percent. Further, the first and second convex members 12, 16 generally have a substantially similar shape such that the nip gap 20 defined between the first and second convex members 12, 16 is symmetrical relative to a center axis of the nip gap 20. However, the first and second convex members 12, 16 may have complimentary shapes that are not substantially uniform and continuous. For example, the first and second convex members 12, 16 may have a complimentary conical shape.

In certain embodiments, the first convex member 12 comprises a first cylindrical roller and the second convex member 16 comprises a second cylindrical roller.

The first and second convex members 12, 16 may be solid, hollow, or combinations thereof. For example, when the first and second convex members 12, 16 are the first and second cylindrical rollers, the first and second cylindrical rollers may have a hollow interior such that the first and cylindrical rollers have a tube shape or the first and second cylindrical rollers may be solid.

The first and second convex members 12, 16 may comprise the same or different materials. Further, each of the first and second convex members 12, 16 may independently comprise a continuous material or combinations of different materials. The first and second convex members 12, 16 generally comprise a material that is compatible with the melt of the semiconductor material. For example, the material of the first and second convex members 12, 16 is compatible with the melt of the semiconductor material if the material does not melt or soften from contact with the melt of the semiconductor material or from exposure to heat from the melt of semiconductor material. As a further example, the material of the first and second convex members 12, 16 may be thermally stable and/or chemically inert to the melt of the semiconductor material, and therefore non-reactive or substantially non-reactive with the melt of the semiconductor material.

Specific examples of materials suitable for the first and second convex members 12, 16 include refractory materials such as fused silica, graphite, silicon carbide, vitreous carbon, diamond-like carbon, silicon nitride, single crystal or polycrystalline silicon, as well as combinations and composites of these materials. In certain embodiments, the material of the first and second convex members 12, 16 is vitreous silica. When the first and/or second convex members comprise a combination of materials, at least a portion of the first and/or second convex members comprises at least one of the refractory materials above. In such embodiments, the external surfaces of the first and/or second convex members comprise at least one of these refractory materials. Alternatively, only a portion of the external surface of the first and/or second convex members comprises at least one of these refractory materials. When the external surfaces of the first and/or second convex members includes the arced portion for less than 360 degrees of the perimeter of the first and/or second convex members, the arced portion comprises at least one of these refractory materials. Such an arc portion may comprise at least one of these refractory materials for its entirety, or for less than its entirety. The refractory materials of the first and second convex members 12, 16 are for contacting the melt of the semiconductor material.

When the first and/or second convex members comprise a combination of materials, the first and second convex members 12, 16 may comprise materials that are suitable for supporting the refractory materials. For example, the refractory materials may be utilized in combination with metals, alloys, ceramics, plastics, and composites and/or combinations thereof. When such combinations are utilized in the first and/or second convex members, the relative thickness of the refractory materials in the first and/or second convex members is a factor of, among other things, the desired heat transfer kinetics between the first and second convex members 12, 16 and the melt of the semiconductor material. To this end, different refractory materials have different specific heat capacities, and thus the relative thickness of the refractory materials in the first and second convex members 12, 16 is also a factor of the particular refractory materials utilized. As one specific example, when the first and second convex members 12, 16 comprise vitreous silica, the relative thickness of the refractory materials in the first and second convex members 12, 16 is typically at least about 250 micrometers (μm). Alternatively, when the first and second convex members 12, 16 comprise silicon carbide, the relative thickness of the refractory materials in the first and second convex members 12, 16 is typically at least about 170 micrometers (μm) because silicon carbide has a much greater specific heat capacity than vitreous silica.

The refractory materials of the first and second convex members 12, 16 may be in the form of a monolith or wafer. Further, the refractory materials of the first and second convex members 12, 16 may comprise a porous or a non-porous body, optionally having one or more porous or non-porous coatings. The refractory materials of the first and second convex members 12, 16 may be characterized by features including shape, dimension, surface area, surface roughness, etc. One or more of these features may be uniform or non-uniform. For example, the refractory materials may have a particular surface roughness or protrusions for imparting the sheet of semiconductor material with the surface roughness of the refractory materials of the first and/or second convex members.

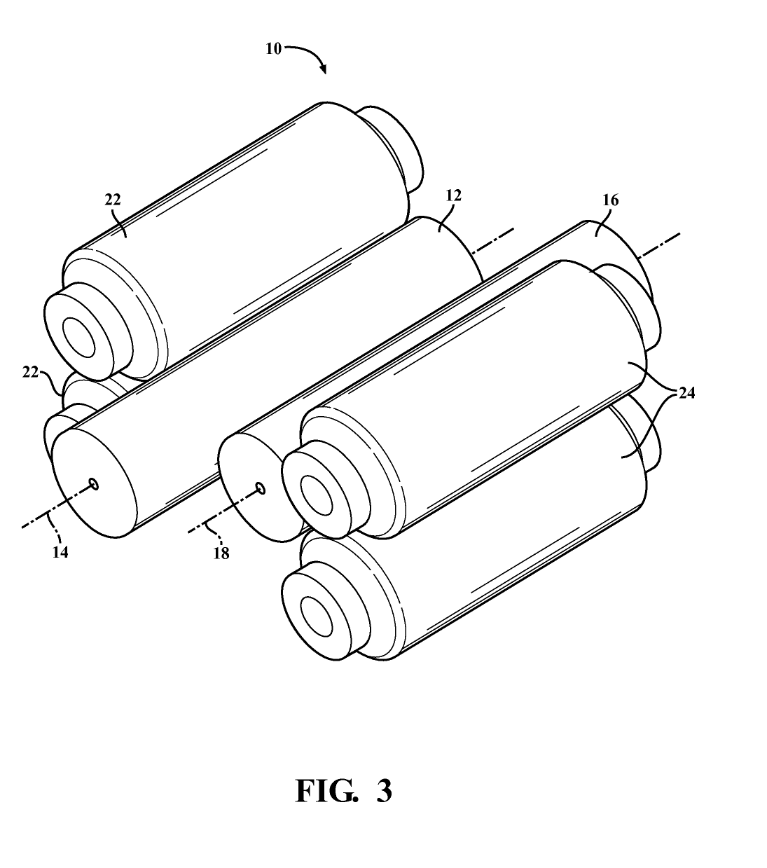

As shown in FIGS. 2 and 3, in certain embodiments in which the first and second convex members 12, 16 are the first and second cylindrical rollers, the system 10 further comprises a first pair of cylinders 22 adjacent to and in contact with the first cylindrical roller. In such embodiments, the system 10 may further comprise a second pair of cylinders 24 adjacent to and in contact with the second cylindrical roller for cradling the second cylindrical roller. The first pair of cylinders 22 is disposed opposite the nip gap 20 from the first cylindrical roller, and the second pair of cylinders 24 is disposed opposite the nip gap 20 from the second cylindrical roller. The first and second pair of cylinders 22, 24 may independently comprise any of the materials described above relative to the first and second convex members 12, 16, although unlike the first and second cylindrical rollers, the first and second pair of cylinders 22, 24 need not, but may, include any of the refractory materials. Further, the first and second pair of cylinders 22, 24 may independently be hollow or solid in shape. Because the first and second pair of cylinders 22, 24 are in contact with the first and second cylindrical rollers as the first and second cylindrical rollers are cradled by the first and second pair of cylinders 22, 24, the first and second pair of cylinders 22, 24 generally have a smooth surface free from contaminants that could otherwise be transferred to the external surfaces of the first and second cylindrical rollers. In certain embodiments, the first and second pair of cylinders 22, 24 are formed from a metal or alloy, such as carbon steel, stainless steel, or a nickel-based superalloy. Such metals or alloys may include corrosion inhibitors, e.g. as coatings, such as chromium or aluminum oxide.

Each of the cylinders of the first and second pair of cylinders 22, 24 has an axis that is substantially parallel with the first and second axes 14, 18 of the first and second cylindrical rollers 22, 24. The first and second pair of cylinders 22, 24 are rotatable about these axes. The first and second pair of cylinders 22, 24 are typically utilized to prevent the first and second cylindrical rollers from being subjected to bending loads. Instead, the first and second pair of cylinders 22, 24 ensure that the first and second cylindrical rollers are subject only to compressive loads. To this end, the first and second pair of cylinders 22, 24 are generally supported in bearings, whereas the first and second cylindrical rollers are generally not supported by bearings. Instead, the first and second cylindrical rollers are generally supported by the first and second pair of cylinders 22, 24 as the first and second pair of cylinders 22, 24 cradles the first and second cylindrical rollers.

In certain embodiments, the first convex member 12 includes a first coupling member 26 and the second convex member 16 includes a second coupling member 28 for enabling rotation of the first and second convex members 12, 16. The first and second coupling members 26, 28 may be coupled to any portion of the first and second convex members 12, 16, respectively, so long as the first and second coupling members 26, 28 are capable of enabling rotation of the first and second convex members 12, 16. In certain embodiments, the first and second coupling members 26, 28 are coupled to opposing ends of the first and second convex members 12, 16. The first and second coupling members 26, 28 may rotate the first and second convex members 12, 16 via motors or other suitable methods of providing rotational drive torque, such as manual rotation. Typically, the first and second coupling members 26, 28 are independently coupled to a first motor and a second motor 40, 42, respectively, for providing the rotational drive torque.

In alternative embodiments including the first and second pair of cylinders 22, 24, one or both of the cylinders of the first pair of cylinders 22 and one or both of the cylinders of the second pair of cylinders 24 may include coupling members for rotating the first and second cylindrical rollers as the first and second cylindrical rollers are cradled by the first and second pair of cylinders 22, 24.

In various embodiments, the first and second convex members 12, 16 may be adjustable from an initial position to at least an operating position along an axis perpendicular to the first and second axes 14, 18. In such embodiments, the first and second convex members 12, 16 may be in nominal contact with one another in the initial position and a width of the nip gap 20 is defined in the operating position as the melt of the semiconductor material, or a partially or wholly solidified deposit formed therefrom, passes therethrough. The nip gap 20 defined by the first and second convex members 12, 16 while the system 10 is in the operating position generally corresponds to a desired thickness of the sheet of semiconductor material.

In these embodiments, the first and second convex members 12, 16 are typically in nominal contact with one another in the initial position via springs, which compress as the melt of the semiconductor material passes through the nip gap 20, thereby adjusting the first and second convex members 12, 16 into the operating position.

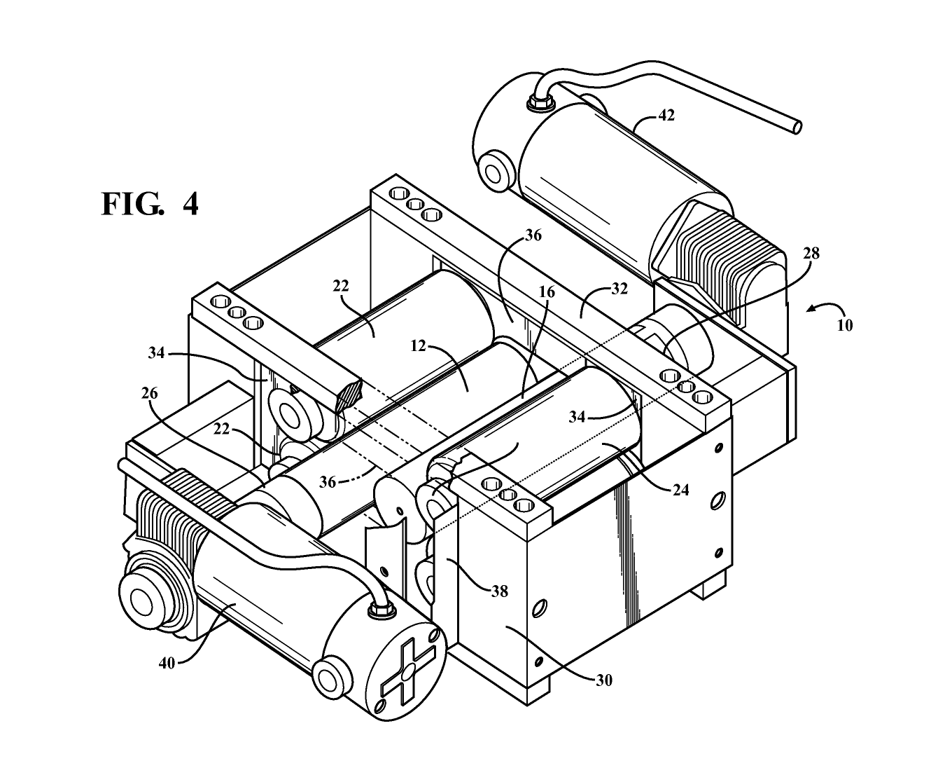

FIG. 4 illustrates an embodiment in which the first and second convex members 12, 16 are the first and second cylindrical rollers, and in which the system 10 includes the first and second pair of cylinders 22, 24 to cradle the first and second cylindrical rollers, respectively. The first and second cylindrical rollers, along with the first and second pair of cylinders 22, 24, extend along the first and second axes 14, 18 between first and second ends. Each of the first and second ends of the first and second cylindrical rollers includes a frame member 30, 32. The first and second pair of cylinders 22, 24 may each be supported in bearings by a support plate 34, which is disposed in the frame member 30, 32 of the system 10 for holding each of the first and second pair of cylinders 22, 24. In this embodiment, the first and second cylindrical rollers are not supported in bearings. Instead, the first and second cylindrical rollers are cradled by the first and second pair of cylinders 22, 24 such that the first and second cylindrical rollers extend laterally to or through the frame members 30, 32 without being in contact therewith. An adjustable plate 36 is disposed adjacent to the support plate 34 in each of the frame members 30, 32 along the axis perpendicular to the first and second axes 14, 18. The first pair of cylindrical rollers 22 is supported in bearings by the support plate 34 at the first end and by the adjustable plate 36 at the second end, whereas the second pair of cylindrical rollers 24 is supported in bearings by the adjustable plate (not shown) at the first end and by the support plate (not shown) at the second end. This configuration allows for each of the first and second cylindrical rollers 22, 24 to be adjustable along the axis perpendicular to the first and second axes 14, 18. In other embodiments, the first cylindrical roller may be supported at both the first and the second ends by the adjustable plates, whereas the second cylindrical roller is supported at both the first and second ends by the support plates (or vice versa) such that only one of the first and second cylindrical rollers is adjustable along the axis perpendicular to the first and second axes 14, 18. The adjustable plate 36 is in contact with the spring opposite the support plate in each of the frame members 30, 32 such that the adjustable plate 36 and the support plate 34 are optionally in nominal contact with one another at the initial position. As the melt of the semiconductor material passes through the nip gap 20, the springs compress, thereby adjusting the system 10 to the operating position as the adjustable plates 36 move away from the support plates 34 along the axis perpendicular to the first and second axes 14, 18 in each of the frame members 30, 32. Each of the frame members 30, 32 may optionally include a shim 38 disposed between the adjustable plate 36 and the respective frame member 30, 32 to adjust the nip gap 20 in real time. Such shims 38 allow for the adjustment of the system 10 relative to the nip gap 20 so that the system 10 can be utilized to form sheets of semiconductor material having different thicknesses without necessitating reconstruction or altering of the system. Alternatively, different springs having different compression forces or other physical properties may be utilized in addition to or in lieu of the shims 38. The frame members 30, 32, support plates 34, and adjustable plates 36 are generally formed from a rigid material, such as metal, metal alloy, or ceramic, or combinations/composites thereof.

The method comprises applying a melt of the semiconductor material on an external surface of at least one of the first convex member 12 and the second convex member 16. The step of applying the melt of the semiconductor material on the external surface of at least one of the first and second convex members 12, 16 forms a deposit on the external surface of at least one of the first and second convex members 12, 16. In particular, at least a portion of the melt of the semiconductor material undergoes a liquid-to-solid phase transformation upon contacting the external surface of at least one of the first and second convex members 12, 16 to form the deposit. The deposit may comprise the melt of the semiconductor material, partially solidified semiconductor material, fully solidified semiconductor material, and any combination thereof. In contrast, the sheet of semiconductor material is formed once the deposit passes through the nip gap 20 of the system 10 defined between the first and second convex members 12, 16. Generally, the deposit is at least partially solidified and does not include any portion that comprises a liquid of the melt of the semiconductor material. The deposit is generally ductile and capable of plastic deformation under stress as the deposit passes through the nip gap 20 of the system.

The melt of the semiconductor material is generally applied such that the melt of the semiconductor material contacts the external surfaces of both the first and second convex members 12, 16 just above the nip gap 20 of the system. At the initial position of the system, the first and second convex members 12, 16 are typically in nominal contact with one another such that the melt of the semiconductor material cannot pass through the nip gap 20 without contacting the external surface of at least one of the first and second convex members 12, 16. Because the melt of the semiconductor material undergoes a liquid-to-solid phase transformation upon contacting at least one of the first and second convex members 12, 16, it is generally desirable to apply the melt of the semiconductor material adjacent to, i.e., above, the nip gap 20 to minimize compressive forces associated with passing a solidified deposit of the melt of the semiconductor material through the nip gap 20.

The melt of the semiconductor material is generally disposed in a vessel (e.g. a crucible) and disposed, e.g. poured, on the external surface of at least one of the first convex member 12 and the second convex member. The first and second convex members 12, 16 may be disposed in the horizontal plane such that melt of the semiconductor material is poured via gravity. Alternatively, the first and second convex members 12, 16 may be disposed in the vertical plane such that the melt of the semiconductor material is introduced into the system 10 in a direction perpendicular to that of gravitational pull. The melt of the semiconductor material may be provided or obtained by melting a suitable semiconductor material in the vessel. The vessel is generally formed from a high temperature or refractory material chosen from vitreous silica, graphite, silicon carbide, vitreous carbon, and silicon nitride. Alternatively, the vessel may be formed from a first high temperature or refractory material and provided with an internal coating of a second high temperature or refractory material where the internal coating is adapted to be in contact with the melt of the semiconductor material. The semiconductor material may be silicon. In addition to silicon or alternatively, the melt of the semiconductor material may be chosen from alloys and compounds of silicon, germanium, alloys and compounds of germanium, gallium arsenide, alloys and compounds of gallium arsenide, and combinations thereof. For example, the silicon may be pure, e.g., intrinsic or i-type silicon; alternatively the silicon may be doped, e.g., silicon containing an n-type or p-type dopant.

The melt of the semiconductor material may comprise at least one non-semiconducting element that may form a semiconducting alloy or compound. For example, the melt of the semiconductor material may comprise gallium arsenide (GaAs), aluminum nitride (AlN) or indium phosphide (InP).

According to various embodiments, the melt of the semiconductor material may be pure or doped. Example dopants, if present, include boron, phosphorous, or aluminum, and may be present in any suitable concentration, e.g. 1-100 ppm, which may be chosen based on, for example, the desired dopant concentration in the sheet of the semiconductor material.

At least one heating element may be utilized to form the melt of the semiconductor material and/or maintain the melt of the semiconductor material at a desired temperature. Examples of suitable heating elements include resistive or inductive heating elements, infrared (IR) heat sources (e.g., IR lamps), and flame heat sources. An example of an inductive heating element is a radio frequency (RF) induction heating element. RF induction heating may provide a cleaner environment by minimizing the presence of foreign matter in the melt of the semiconductor material.

Prior to applying the melt of the semiconductor material on the external surface of at least one of the first and second convex members 12, 16, the bulk temperature of the melt of the semiconductor material (T_{S}) is greater than or equal to a melting point temperature of the semiconductor material utilized (T_{M}) such that (T_{S}) (T_{M}). In embodiments where the melt of the semiconductor material comprises silicon, the bulk temperature of the molten silicon may range from 1414 to 1550, alternatively from 1450 to 1490° C., e.g. 1460° C.

The external surfaces of the first and second convex members 12, 16 may have a selectively controlled temperature, e.g. the external surfaces of the first and second convex members 12, 16 may be cooled and/or heated, or the external surfaces of the first and second convex members 12, 16 may merely have ambient temperatures. The external surfaces of the first and second convex members 12, 16 typically have substantially the same temperature (T_{R}). The temperature of the external surfaces of the first and second convex members 12, 16 is less than the bulk temperature of the melt of the semiconductor material ((T_{R})<(T_{S})) and also less than the melting point temperature of the semiconductor material utilized ((T_{R})<(T_{M})) such that a temperature difference between the external surfaces of the first and second convex members 12, 16 and the melt of the semiconductor material will induce a liquid-to-solid phase transformation of the melt of the semiconductor material. The temperature (T_{R}) of the external surfaces of the first and second convex members 12, 16 is typically from greater than 0 to 500, alternatively from 100 to 400, alternatively from 100 to 200, ° C. The magnitude of the temperature difference between (T_{R}) and (T_{S}) can affect the microstructure and other properties of the sheet of the semiconductor material. The temperature gradient between (T_{R}) and (T_{S}) which may be on the order of, for example, 800° C. or more.

In addition to controlling the temperature gradient of the external surface of at least one of the first and second convex members 12, 16 and the temperature of the melt of the semiconductor material, the temperature of the radiant environment, such as a wall of the vessel, may also be controlled.

The method further comprises rotating the first and second convex members 12, 16 in a direction opposite one another to allow for the deposit to pass through the nip gap 20, thereby forming the sheet of semiconductor material. The deposit passes through the nip gap 20 in a downward direction, typically aided by gravity. In particular, the first and second convex members 12, 16 are rotated towards one another, or towards the nip gap 20. One of the first and second convex members 12, 16 is rotated clockwise while the other of the first and second convex members 12, 16 is rotated counterclockwise.

As set forth above, the first and second convex members 12, 16 may be rotated via numerous different methods. For example, the first and second convex members 12, 16 may be rotated manually (e.g. by a handle), or by the first and second coupling members 26, 28, which are typically independently coupled to the first motor and the second motor 40, 42 for providing the rotational drive torque. In other embodiments, when the first and second convex members 12, 16 are the first and second cylindrical rollers, and the system 10 includes the first and second pair of cylinders 22, 24, one or both of the first pair of cylinders 22 and one or both of the second pair of cylinders 24 may be rotated, thereby initiating rotation of the first and second cylindrical rollers. The first and second pair of cylinders 22, 24 may be rotated by similar methods as the first and second convex members 12, 16.

The first and second convex members 12, 16 are generally rotated in a direction opposite one another at substantially the same angular speed. The angular speed of the first and second convex members 12, 16 is a function of several variables, including the desired thickness of the sheet of semiconductor material, the material of the first and second convex members 12, 16, the temperature of the first and second convex members 12, 16, the cross-sectional area of the first and second convex members 12, 16, and the thickness of the nip gap 20. Because it is desirable to rotate the first and second convex members 12, 16 in a direction opposite one another at substantially the same angular speed, the first and second convex members 12, 16 are typically rotated via the first and second motors 40, 42, which are coupled to the first and second convex members 12, 16 via the first and second coupling members 26, 28. Such motors 40, 42 minimize any variability in angular speed. In certain embodiments, the angular speed may be changed (i.e., increased or decreased) for one or both of the first and second convex members 12, 16 before, during, and/or after the application of the melt of the semiconductor material to the external surface of at least one of the first and second convex members 12, 16. The first and second convex members 12, 16 may be rotated at different angular speeds, particularly if the first and second convex members 12, 16 differ from one another in size or dimension. The angular speed at which the first and second convex members 12, 16 are rotated is generally selected to provide a desired contact time between the external surfaces of the first and second convex members 12, 16 and the melt of the semiconductor material prior to the sheet of semiconductor material exiting the nip gap 20. This contact time is typically from greater than 0 to 10, alternatively from 0.5 to 5, seconds. For example, when the first and second convex members 12, 16 each have a diameter of about 50 millimeters (mm), the angular speed of the first and second convex members 12, 16 is typically about 6 rotations per minute (rpm).

The length of time or time period during which the melt of the semiconductor material is in contact with the external surface of at least one of the first and second convex members 12, 16 is typically sufficient to allow the sheet of the semiconductor material to partially solidify prior to passing through the nip gap 20. This time period may be varied appropriately based on various parameters, such as the temperatures and heat transfer properties of the system, and the desired properties of the sheet of the semiconductor material. The time period is typically from greater than 0 to 30 seconds. However, this time period does not account for the time period during which the sheet of semiconductor material may be in contact with the first and/or second convex members 12, 16 after its formation, which may extend significantly beyond 30 seconds contingent on how quickly the sheet of semiconductor material 14 is separated from the first and/or second convex members 12, 16.

Certain aspects of the sheet of semiconductor material are determined by the application of the melt of the semiconductor material to the external surface of at least one of the first and second convex members 12, 16. For example, when the melt of the semiconductor material is applied on the external surface of at least one of the first and second convex members 12, 16, the sheet of semiconductor material is formed as the deposit begins to solidify and passes through the nip gap 20. To the extent the melt of the semiconductor material solidifies to form a deposit having a thickness greater than the thickness of the nip gap 20, the nip gap 20 generally flattens the deposit such that the deposit has the same thickness as the nip gap 20. To this end, the convex members are generally rotated and the melt of the semiconductor material is applied such that the melt of the semiconductor material does not fully solidify prior to passing through the nip gap 20, which can subject the first and second convex members 12, 16 to compressive forces. Rather, the melt of the semiconductor material is generally partially solidified as it passes through the nip gap 20, after which the sheet of semiconductor material is formed. The melt of the semiconductor material, even when partially solidified, is substantially more ductile and malleable than a solid semiconductor material, e.g. if the melt of the semiconductor material is fully solidified prior to passing through the nip gap 20.

When the melt of the semiconductor material is applied on the external surface of but one of the first and second convex members 12, 16, the sheet of semiconductor material formed typically has a continuous cross sectional area and a continuous grain structure across the thickness of the sheet of semiconductor material. Conversely, when the melt of the semiconductor material is applied on the external surface of both the first and second convex members 12, 16, the melt of the semiconductor material forms a first deposit on the first convex member 12 and a second deposit on the second convex member. The first and second deposits are fused together at the nip gap 20 to form the sheet of semiconductor material. As such, when the melt of the semiconductor material is applied on the external surface of both the first and second convex members 12, 16, the sheet of semiconductor material generally does not have a continuous grain structure throughout its thickness because the respective grains are formed in the first and second deposits, the fusing of the first and second deposits to form the sheet of semiconductor material does not alter the individual grain characteristics of the first and second deposits, respectively.

The first and second convex members 12, 16 may optionally be vibrated as the melt of the semiconductor material is applied to the external surface of at least one of the first and second convex members 12, 16. Typically, the first and second convex members 12, 16 are maintained essentially stationary as the melt of the semiconductor material is applied to the external surface of at least one of the first and second convex members 12, 16.

The sheet of the semiconductor material may be removed or separated from the external surface of at least one of the first and second convex members 12, 16 using, for example, differential expansion and/or mechanical assistance. Alternatively, the sheet may remain on the external surface of at least one of the first and second convex members 12, 16 as a supported article of semiconductor material. Typically, however, the sheet of semiconductor material separates from the external surfaces of the first and second convex members 12, 16 after passing through the nip gap 20 of the system 10 and becomes freestanding. Alternatively, the system 10 may include a blade on one or both of the external surfaces of the first and second convex members 12, 16 below the nip gap 20 for separating the sheet of semiconductor material from the external surfaces. Further, such a blade may be utilized to remove any residual semiconductor material adhered to the external surfaces of the first and second convex members 12, 16, or to continuously remove contaminants therefrom as the first and second convex members 12, 16 rotate.

A composition of an atmosphere surrounding the system 10 can be controlled before, during, and/or after application of the melt of the semiconductor material to the external surface of at least one of the first and second convex members 12, 16. For example, utilizing vitreous silica for the refractory materials of the first and/or second convex members and/or the vessel may lead to oxygen contamination of the sheet of the semiconductor material. Accordingly, oxygen contamination may be mitigated or substantially mitigated, by melting the semiconductor material and forming the sheet of semiconductor material in a low-oxygen environment, comprising, for example, a dry mixture of hydrogen (e.g., less than 1 ppm water) and an inert gas such as argon, krypton or xenon. A low-oxygen environment may include one or more of hydrogen, helium, argon, or nitrogen. In one exemplary embodiment, the atmosphere may be chosen from an Ar/1.0 wt % H₂ mixture or an Ar/2.5 wt % H₂ mixture. In such embodiments, the system 10 is generally a closed system, i.e., the atmosphere of the system 10 is not influenced by its surroundings.

The method may be operated as a batch method or a continuous method. In the batch method, the first and second convex members 12, 16 need only have the arced portion. In the continuous method, the first and second convex members 12, 16 are generally the first and second cylindrical rollers or other elliptical members so that the first and second convex members 12, 16 can continuously rotate as the melt of the semiconductor material is continuously applied on the external surface of at least one of the first and second convex members 12, 16.

Because the sheet of semiconductor material may result from fusing the first and second deposits, it may be desirable to modify the grain structure of the resulting sheet of semiconductor material. To this end, in certain embodiments, the method may further comprise at least partially remelting the sheet of semiconductor material to form a remelted semiconductor material and recrystallizing the remelted semiconductor material. Alternatively, remelting and recrystallizing the sheet of semiconductor material may not be desirable, particularly when the sheet of semiconductor material is not formed from fusing the first and second deposits together, e.g. when the sheet of semiconductor is formed from depositing the melt of semiconductor material on but one of the external surfaces of the first and second convex members 12, 16.

The thickness of the sheet of the semiconductor material is a function of, among other things, the nip gap 20, the angular speed of the first and second convex members 12, 16, and the time during which the melt of the semiconductor material is in contact with the external surface of at least one of the first and second convex members 12, 16. In certain embodiments, the thickness of the sheet of the semiconductor material is from 100 to 400, alternatively from 125 to 350, alternatively from 150 to 300, alternatively from 175 to 250, microns. Further, sheet of the semiconductor material has a total thickness variability (TTV) of less than 30, alternatively less than 25, alternatively less than 20, alternatively less than 15, alternatively less than 10, alternatively less than 5, alternatively less than 4, alternatively less than 3, alternatively less then 2, alternatively less than 1, percent. TTV means the normalized maximum difference in thickness between the thickest point and the thinnest point within a sampling area of a sheet. TTV is equal to (tₘₐₓ−tₘᵢₙ)/t_{target}, where tₘₐₓ and tₘᵢₙ are the maximum and minimum thicknesses within the sampling area and t_{target} is the target thickness. The sampling area may be defined as the whole or a portion of the sheet. TTV may be measured in accordance with ASTM F657-92 (1999).

If desired, the physical dimensions of the sheet of semiconductor material may also be modified by altering the system 10 itself. For example, modifying the first and second convex members 12, 16 such that the first and second axes 14, 18 intersect to form an acute angle of three degrees could prepare a sheet of semiconductor material having a wedge shape, i.e., having a non-uniform thickness across the cross section of the sheet of semiconductor material.

The disclosed methods can be used to produce sheets of semiconductor material having one or more desired attributes related to, for example, total thickness, TTV, impurity content and/or surface roughness. These sheets, such as silicon sheets, may be used to for electronic devices, e.g. photovoltaic devices. For example, when the sheets comprise silicon, the sheets generally comprise polycrystalline silicon. By way of example, an as-formed silicon sheet may have real dimensions of about 156 mm×156 mm, a thickness in a range of 100 μm to 400 μm, and a substantial number of grains larger than 1 mm. However, if operated as a continuous process, the system 10 may form sheets of semiconductor materials having a continuous length substantially greater than 156 mm, although such sheets of semiconductor materials may be modified or cut dependent on the desired dimensions of the sheets of semiconductor materials.

The sheet of semiconductor material may define one or more (e.g. up to 30) apertures therethrough. The apertures may enable the sheet of semiconductor material defining such apertures to be used to prepare a metallization wrap-through photovoltaic cell.

The sheet of semiconductor material may be utilized in various applications and components, such as electronic components or devices comprising the sheet of semiconductor material. For example, the sheet of semiconductor material may be utilized in integrated circuits, light emitting diodes, photovoltaic cells, microprocessors, and other electronic components, which may be incorporated into computers, digital cameras, and photovoltaic cell modules.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

The following examples are intended to illustrate embodiments and are not to be viewed in any way as limiting to the scope of the disclosure.

### EXAMPLES

### Example 1

A system in accordance with the disclosure comprises, as the first and second convex members, first and second cylindrical rollers, as illustrated in FIGS. 2-4.

The system is operated in accordance with the following equation:

$$a > \frac{( Q / W )}{d \cdot R \cdot ω} > b$$

wherein a is 1.5, alternatively 1.2, alternatively 1; b is 0.5, alternatively 0.8, alternatively 0.9; Q is the volumetric flow rate of the melt of semiconductor material; W is the width of the first and second cylindrical rollers (or the length of the first and second cylindrical rollers along the first and second axes, respectively), d is the length of the nip gap, R is the radius of each of the first and second cylindrical rollers; and ω is the rotational speed of the first and second cylindrical rollers.

In particular, in this Example, the first and second cylindrical rollers each comprise high purity fused silica, have a diameter of 50 millimeters (mm), and a width (or the length of the first and second cylindrical rollers along the first and second axes, respectively) of 150 millimeters (mm). The nip gap is 200 micrometers (μm). 30 millimeters (mL) of molten silicon having a temperature of 1500° C. is ladled above the first and second cylindrical rollers, which have a temperature of 30° C. The first and second cylindrical rollers are rotated in a direction opposite one another at about 10 rotations per minute (rpm). The system is operated under Ar/1%H2. A sheet of silicon is formed having a width of 20 millimeters (mm), a length of 200 millimeters (mm), and a thickness of 200 micrometers (μm).

As used herein, the singular forms “a,” “an” and “the” include plural referents unless the context clearly dictates otherwise. Thus, for example, reference to a “convex member” includes examples having two or more such “convex members” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a system comprising a nip gap include embodiments where a system consists of a nip gap and embodiments where a system consists essentially of a nip gap.

It is also noted that recitations herein refer to a component being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

What is claimed is:

1. A method of forming a sheet of semiconductor material with a system which comprises a first convex member extending along a first axis and capable of rotating about the first axis, and a second convex member spaced from the first convex member and extending along a second axis and capable of rotating about the second axis, wherein the first and second convex members define a nip gap therebetween and wherein the first and second axes are substantially parallel with one another, said method comprising the steps of:
applying a melt of the semiconductor material on an external surface of at least one of the first convex member and the second convex member to form a deposit on the external surface of at least one of the first and second convex members; and
rotating the first and second convex members in a direction opposite one another to allow for the deposit to pass through the nip gap, thereby forming the sheet of semiconductor material.

2. A method as set forth in claim 1, wherein applying the melt of the semiconductor material forms a first deposit on the first convex member and a second deposit on the second convex member and wherein the first and second deposits are fused together at the nip gap to form the sheet of semiconductor material.

3. A method as set forth in claim 1, wherein rotating the first and second convex members comprises rotating the first and second convex members in a direction opposite one another at substantially the same angular speed.

4. A method as set forth in claim 1, wherein the first convex member comprises a first cylindrical roller and the second convex member comprises a second cylindrical roller.

5. A method as set forth in claim 4, wherein the system further comprises a first pair of cylinders adjacent to and in contact with the first cylindrical roller for cradling the first cylindrical roller and a second pair of cylinders adjacent to and in contact with the second cylindrical roller for cradling the second cylindrical roller.

6. A method as set forth in claim 4, wherein at least one of the first and second cylindrical rollers are adjustable from an initial position to at least an operating position along an axis perpendicular to the first and second axes such that the first and second cylindrical rollers are in nominal contact with one another in the initial position and a width of the nip gap is defined in the operating position as the solid semiconductor material passes therethrough.

7. A method as set forth in claim 1, wherein (a) the first and second convex members have substantially the same temperature of from 100 to 400° C. (T_{R}) and the melt of the semiconductor material has a temperature of (T_{S}) such that T_{S}>T_{R}; (b) the sheet of the semiconductor material has a thickness of from 25 to 500 microns; (c) the sheet of semiconductor material comprises silicon, germanium, compounds thereof, alloys thereof, and combinations thereof; (d) the melt of the semiconductor material comprises molten silicon, molten germanium, molten gallium arsenide, compounds thereof, alloys thereof, or combinations thereof; (e) the first and second convex members independently comprise a material selected from the group of fused silica, graphite, silicon carbide, vitreous carbon, diamond-like carbon, silicon nitride, single crystal or polycrystalline silicon, composites thereof, and combinations thereof; or (f) any combination of (a)-(e).

8. A method as set forth in claim 1, further comprising the steps of at least partially remelting the sheet of semiconductor material to form a remelted semiconductor material and recrystallizing the remelted semiconductor material.

9. A system for forming the sheet of semiconductor material in accordance with the method of claim 1.

10. A sheet of a semiconductor material formed in accordance with the method of claim 1.
